(19) United States
(12) Patent Application Publication
(10) Pub. No.: US 2008/0169806 A1
(43) Pub. Date: Jul. 17, 2008

(54) Hall sensor for linear motor

(75) Inventors: Lieh-Feng Huang, Taichung (TW); Chih-Yu Wang, Taichung (TW)

Correspondence Address: CHARLES E. BAXLEY, ESQ., 90 JOHN STREET, THIRD FLOOR, NEW YORK, NY, 10038, US

(73) Assignee: Hiwin Mikrosystem Corp.

(21) Appl. No.: 11/654,229

(22) Filed: Jan. 16, 2007

(51) Int. Cl. G01R 33/06

(52) U.S. Cl. 324/251

(57) ABSTRACT

A Hall sensor for a coreless linear motor comprises a housing composed of a package segment and a foundation mutually integrated wherein a magnetic sensor and a signal conditioning circuit are packaged and embedded in the package segment by means of infusing resin wherein the signal conditioning circuit has an inductive signal transmission line attached thereto outgoing through an outlet hole provided at one side of the housing. The disclosed Hall sensor is provided for being fastened to a forcer of the linear motor. As the disclosed Hall sensor with an optimized arrangement of the inductive signal transmission line thereof, the present invention contributes to enhancing the precision and reliability of the Hall sensor.

### BACKGROUND OF THE INVENTION

1. Technical Field

The present invention relates to position feedback devices for linear motors, and more particularly, to an improved structure of Hall sensors for being used in a coreless linear motor.

2. Description of Related Art

Some prior arts related to the present invention involve have provided position feedback devices for coreless linear motors. One prior art technical disclosed the implement of a Hall sensor, which surpasses other types of sensors by the unique advantageous features such as small volume, easy installation and low cost. The fundamental principle upon which a Hall sensor functioning as a position feedback device for a linear motor based is that a Hall sensor inducts the variation of the magnetic field generated along the relative displacement between the stator and forcer; transform the magnetic field strength into voltage signals, which are proportionable to the variation of the magnetic field and afterward outputs the resultant signals for non-contact measurement of displacement.

A recent development of Hall sensors is related to integrating a magnetic sensor with a signal conditioning circuit as a single package.

Please refer to FIG. 1 where a conventional Hall sensor is shown. Such conventional Hall sensor comprises primarily an induction package 10 and a foundation 11 wherein the induction package 10 is the prime induction apparatus of the Hall sensor and the foundation 11 is provided for facilitating installing the Hall sensor onto a forcer of a linear motor. For making the induction package 10, the magnetic sensor and the signal conditioning circuit previously arranged in a mold with an inductive signal transmission line 12 extending from the signal conditioning circuit outward the mold are packaged with resin. Then the induction package 10 is put into another mold for a second package process in order to combine the induction package 10 with the foundation 11 in the manner that the outgoing of the transmission line 12 is happened at the foundation 11. The Hall sensor made with foregoing method involving the repeated package processes may become commercially uncompetitive because of the high productive cost for mold manufacturing and complex proceeding procedures.

On the other hand, FIG. 2 is provided for illustrating another conventional Hall sensor, which similarly comprises primarily an induction package 13 and a foundation 14. It differs from previously discussed one by independent induction package 13 and foundation 14 that are combined by means of plural fixing components 15. A magnetic sensor and a signal conditioning circuit are arranged in and integrally packaged with a metal frame 131 of the induction package 13 by a resin as designated by numeral 132 in FIG. 2. As an inductive signal transmission line 16 pierces through the surface of the package 13 directly, part of the transmission line 16 adjacent to the surface of the induction package 13 can come in a bent shape and be hardly covered by a protective pipe 161 attach thereto. This disadvantageously brings the risk of damage or breakage to the transmission line 16 and consequently causes the reliability with respect to signal transmission depressed. Furthermore, as shown in FIG. 3, since the transmission line 16 extends in a direction perpendicular to that of a wire 18 of a forcer 17 where the Hall sensor is to be assembled to, the transmission line 16 may interfere with the combination of the forcer 17 and a base thereof (not shown). Thus, directional limitation and special limitation may occur during the assembling work between the forcer 17 and the Hall sensor or the base.

### SUMMARY OF THE INVENTION

It is the object of the present invention to provide a Hall sensor, which requires less productive cost and presents improved precision as well as reliability by optimizing the arrangement of an inductive signal transmission line thereof.

A Hall sensor for being assembled to a forcer of a coreless linear motor, wherein the side of the forcer corresponding to the location of an inductive signal transmission line attached thereon is determined as an outgoing wire side while the side opposite to the outgoing wire side is defended as a non-outgoing wire side, comprises:

a housing, which includes a package segment and a foundation formed integrally with the package segment wherein the package segment has a package space defined by a plurality of interconnected sidewalls and a bottom plate integrated with the sidewalls at the corresponding edges thereof while the foundation, which has at least one fixing hole and is integrated with the back of the bottom plate, includes a outlet hole disposed on one of the sidewalls leading to the package space; and

an induction package, which is constructed from packaging a magnetic sensor and a signal conditioning circuit in said package space through by infusing resin and has an inductive signal transmission line outgoing from the induction package through the outlet hole.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIG. 1 is showing a conversational Hall sensor;

FIG. 2 is showing another conversational Hall sensor;

FIG. 3 is an applied drawing showing the Hall sensor in FIG. 2 assembled to a forcer of a coreless linear motor;

FIG. 4 is a perspective view of the housing of the Hall sensor according to the present invention;

FIG. 5 is a schematic drawing showing the magnetic sensor and signal conditioning circuit being packaged in the housing as shown in FIG. 4 with resin; and

FIG. 6 is an applied view showing the disclosed Hall sensor assembled to a forcer of a coreless linear motor.

### DETAILED DESCRIPTION OF THE PREFERRED EMBODIMENT

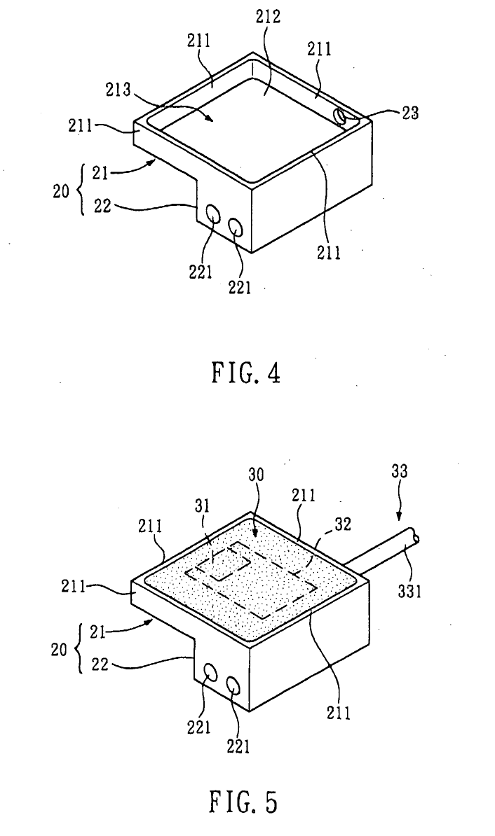

A Hall sensor according to the present invention as depicted in FIGS. 4 and 5 comprises:

a housing 20 made of metal which includes a package segment 21 and a foundation 22 formed integrally with the package segment 21 wherein the package segment 21 has a package space 213 defined by a plurality of interconnected sidewalls 211 and a bottom plate 212 integrated with the sidewalls 211 at the corresponding edges thereof while the foundation 22 which has two fixing holes 221 and is integrated with the back of the bottom plate 212 includes a outlet hole 23 disposed on one of the sidewalls 211 leading to the package space 213; and

an induction package 30, which is constructed from arranging a magnetic sensor 31 and a signal conditioning circuit 32 that are essential elements of the Hall sensor in said package space 213 and an inductive signal transmission line 33 outgoing from the induction package through the outlet hole 23 before infusing resin into the package space 213 to package said components in order to form the induction package 30 in the package segment 21 of the housing 20.

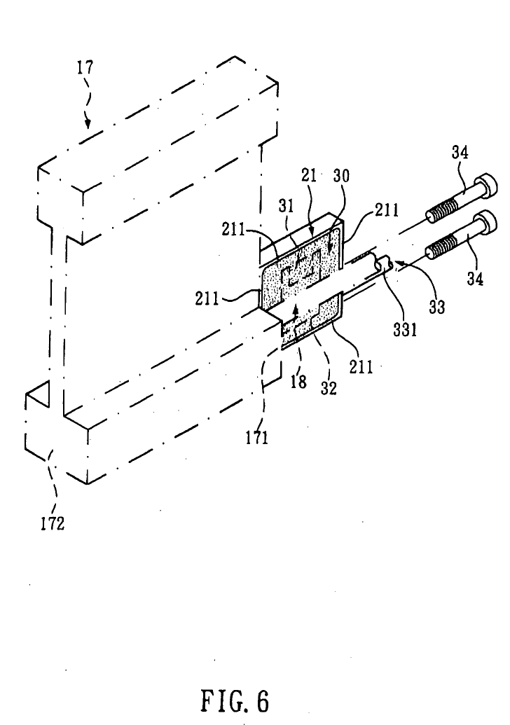

FIG. 6 is an applied view showing the disclosed Hall sensor assembled to a forcer 17 of a known coreless linear motor. It can be seen that the side of the forcer 17 corresponding to the location of a wire 18 attached thereon is determined as an outgoing wire side 171 while the side opposite to the outgoing wire side 171 is defended as a non-outgoing wire side 172. Two fixing components 34 is threaded through the fixing hole 221 of the foundation 22 to attach the disclosed Hall sensor onto the outgoing wire side 171 of the forcer 17 in the manner that the package segment 21 and the induction package 30 are arranged in a direction parallel to the forcer 17. Noteworthily, the outlet hole 23 is deliberately positioned in order to guide the transmission line 33 of the induction package extending in a direction parallel to the wire 18 of the forcer 17.

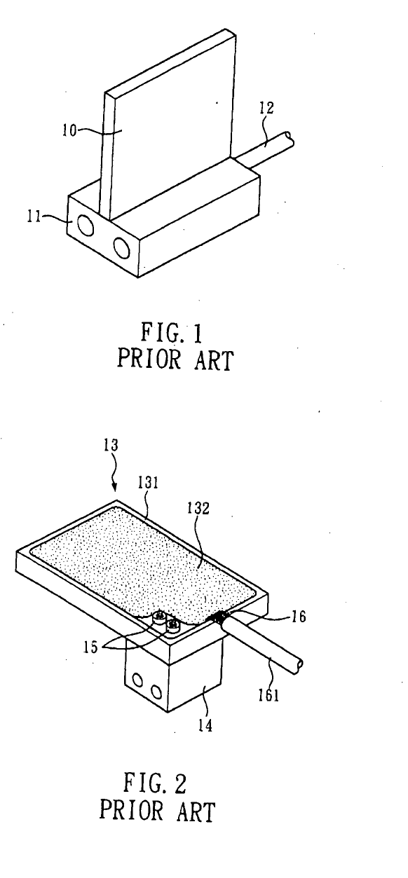

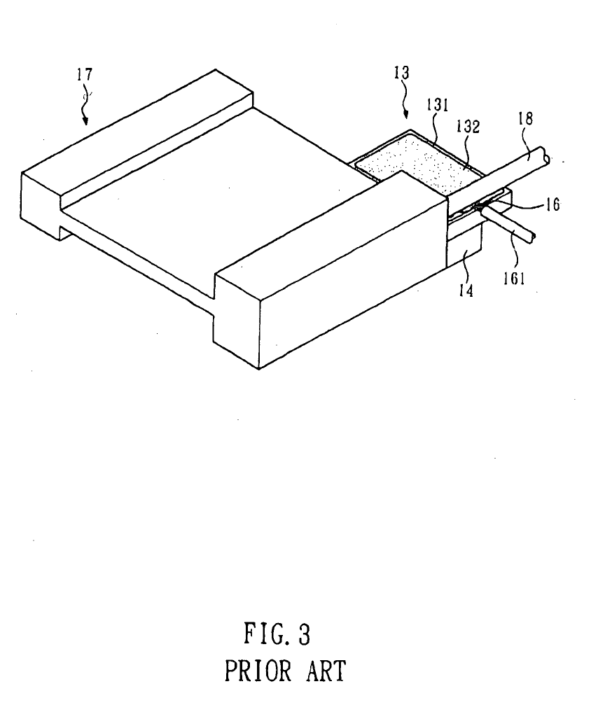

By comparing the disclosed Hall sensor to the conventional one described in FIG. 1, the difference appears obviously in following concepts.

The discussed conventional Hall sensor is made through packaging the magnetic sensor and the signal conditioning circuit that are previously arranged in a mold with resin. Dissimilarly, the disclosed Hall sensor is made through arranging the magnetic sensor 31 and the signal conditioning circuit 32 in the package space 213 of the housing 20 and integrating the components with the housing 20. Thus, the need for the mold implemented in the prior art can be eliminated in the production of the disclosed Hall sensor.

In the discussed prior art, a second package process for combining the induction package with the foundation has to be conducted by using the other mold. Dissimilarly, the foundation 22 of the disclosed Hall sensor is prefabricated on the metal housing 20. Thus, the need for the mold implemented in the second package process of the prior art can be eliminated according to the present invention.

Further, the productive cost of the conventional Hall sensor can be significantly increased for two molds and two package procedures are implemented. However, in the present invention, the Hall sensor manufactured by way of directly embedding the induction package into the housing 20 that is integrally formed with the foundation 22 so that the manufacturing procedures can be simplified and the expense for making said molds can be saved. Thus, in a concept related to productive cost, the disclosed Hall sensor is more economical and competitive.

By comparing the disclosed Hall sensor to the conventional one described in FIG. 2, the difference appears obviously in following concepts.

Though the discussed prior-art Hall sensor implements an improved method for embedding the induction package in the metal frame, it did not give out any solution to the optimal arrangement of the transmission line. In such structure of the discussed conventional Hall sensor, as the transmission line is directly extended from the resin-sealed induction package, it can be easily exposed from the protective pipe attached thereto and can be subject to damage or breakage. Consequently, the reliability thereof is jeopardized. On the other hand, the Hall sensor of the present invention is designed so as to have the outlet hole 23 disposed on one of the sidewalls 211 and leading to the package space 213. By such design, the outlet hole 23 permits the transmission line 33 of the induction package 30 and a protective pipe 331 for wrapping it passing therethrough in a configured manner. Thus, the reliability of signal transmission can be improved for the transmission line 33 is completely protected and appropriately positioned while being ensured from undesired exposedness.

Another problem with respect to the transmission line of the conventional Hall sensor, as described previously, is that as the transmission line is directly extended from the resin-sealed induction package, it comes in a perpendicular direction with respect to the extending direction of the wire of the forcer, and therefore interferes the combination between the forcer and a base thereof. Thus, directional limitation and special limitation may occur during the assembling work between the forcer and the Hall sensor or the base. Differently, the outlet hole 23 of the disclosed Hall sensor is disposed on one of the sidewalls 211 and therefore allows the transmission line 33 outgoing from the induction package 30 at the side thereof so that the transmission line 33 can keep parallel to the wire 18 of the forcer 17 and foresaid directional limitation and special limitation can be overcome.

At last, in the prior art, the foundation is fastened to the bottom of the metal frame with fixing components for which a screwing operation is necessary. Yet in the disclosed Hall sensor, the foundation 22 is combined to the package segment 21 as a whole and no further assembling procedure is required.

As a conclusion, the Hall sensor of the present invention can be a successful solution for overcoming foresaid problems of the prior arts and meet the prime objective of reducing the productive cost thereof. Also, the disclosed Hall sensor presents improved precision and reliability by optimizing the arrangement of the transmission line.

Although a particular embodiment of the invention has been described in detail for purposes of illustration, it will be understood by one of ordinary skill in the art that numerous variations will be possible to the disclosed embodiments without going outside the scope of the invention as disclosed in the claims.

1-4. (canceled)

5. A Hall sensor for a linear motor for being assembled to a forcer of a coreless linear motor, having at least a pair of sides and a wire attached to one of said sides wherein the side of the forcer corresponding to the location of the wire attached thereon is defined as an outgoing wire side while the side opposite to the outgoing wire side is defined as a non-outgoing wire side, comprising:
a housing, which includes a package segment and a foundation formed integrally with the package segment wherein the package segment has a package space defined by a plurality of interconnected sidewalls and a bottom plate integrated with the sidewalls at the corresponding edges thereof, with one of the plurality of interconnected side walls having an outlet hole disposed leading to the package space, and with the bottom plate having a back while the foundation, which has at least one fixing hole and is integrated with the back of the bottom plate; and
an induction package, which is constructed from packaging a magnetic sensor and a signal conditioning circuit in said package space through by infusing resin and has an inductive signal transmission line outgoing from the induction package through the outlet hole wherein the inductive signal transmission line of the Hall sensor has an outgoing direction parallel to the outgoing direction of the wire of the forcer.

6. A Hall sensor for a linear motor for being assembled to a forcer of a coreless linear motor, having at least a pair of sides and a wire attached to one of said sides wherein the side of the forcer corresponding to the location of the wire attached thereon is defined as an outgoing wire side while the side opposite to the outgoing wire side is defined as a non-outgoing wire side, comprising:
a housing, which includes a package segment and a foundation formed integrally with the package segment wherein the package segment has a package space defined by a plurality of interconnected sidewalls and a bottom plate integrated with the sidewalls at the corresponding edges thereof, with one of the plurality of interconnected side walls having an outlet hole disposed leading to the package space, and with the bottom plate having a back while the foundation, which has at least one fixing hole and is integrated with the back of the bottom plate; and
an induction package, which is constructed from packaging a magnetic sensor and a signal conditioning circuit in said package space through by infusing resin and has an inductive signal transmission line outgoing from the induction package through the outlet hole wherein the foundation is fastened to the outgoing wire side of the forcer for the purpose of combining the Hall sensor with the forcer and wherein the inductive signal transmission line of the Hall sensor has an outgoing direction parallel to the outgoing direction of the wire of the forcer.
